(19) United States
(12) Patent Application Publication
(10) Pub. No.: US 2014/0110818 A1
(43) Pub. Date: Apr. 24, 2014

(54) RANDOM ACCESS MEMORY DEVICE AND MANUFACTURING METHOD FOR NODES THEREOF

(71) Applicant: INOTERA MEMORIES, INC., TAOYUAN COUNTY (TW)

(72) Inventors: TZUNG-HAN LEE, TAIPEI CITY (TW); CHUNG-LIN HUANG, TAOYUAN COUNTY (TW)

(73) Assignee: INOTERA MEMORIES, INC., TAOYUAN COUNTY (TW)

(21) Appl. No.: 13/839,477

(22) Filed: Mar. 15, 2013

(30) Foreign Application Priority Data
Oct. 19, 2012 (TW) 101138663

(51) Int. Cl. H01L 21/762; H01L 29/06

(52) U.S. Cl. CPC H01L 21/76224; H01L 29/0649
USPC 257/516; 438/424

(57) ABSTRACT

A manufacturing method for the nodes of the RAM device, includes the steps as follows: forming a STI layer on a substrate to divide the substrate into several active areas; sequentially forming a first insulating layer and a hard mask layer on the substrate; etching the first insulating layer to form a first hole for exposing the STI layer and partial of the active areas; filling a conductive material in the first hole to form a conductor; forming a protective layer on the top surface of the conductor, wherein each protective layer has an opening aligning the STI layer; etching the conductor from the opening until the STI layer to form a second hole for exposing the STI layer, wherein each conductor is divided into two nodes by the second hole arranged therebetween; and forming a second insulating layer in the second hole for electrically isolating the nodes.

### BACKGROUND OF THE INVENTION

1. Field of the Invention

The instant disclosure relates to a semi-conductor device and a manufacturing method thereof; more particular, to a random access memory (RAM) device and a manufacturing method for the nodes thereof.

2. Description of Related Art

Today's semiconductor industry gradually tends to the miniaturized design, so that the adjacent components disposed on the substrate have a narrowing distance. Please refer to FIGS. 1 and 1A, which show a conventional RAM device. The conventional RAM device has a substrate 1a, an insulating layer 2a, and an isolation layer 3a. The substrate 1a is defines as a plurality of active areas 11a by the isolation layer 3a. The insulating layer 2a is etched to form two holes 21a. That is to say, the intermediate portion 22a of the insulating layer 2a, which is disposed on the isolation layer 3a, separates the two holes 21a, and each hole 21 is used for being filling to form a node (not shown).

However, when forming the holes 21, the bottom of the intermediate portion 22a of the insulating layer 2a is etched to form a lateral etching area 23a. That is to say, the width of the intermediate portion 22a is gradually reduced from the top of the intermediate portion 22a to the isolation layer 3a, so that the distance between the nodes, which are arranged at two opposite sides of the intermediate portion 22a, is gradually reduced to cause short circuit therebetween easily.

To achieve the abovementioned improvement, the inventors strive via industrial experience and academic research to present the instant disclosure, which can provide additional improvement as mentioned above.

### SUMMARY OF THE INVENTION

One embodiment of the instant disclosure provides a RAM device and a manufacturing method for the nodes of the RAM device, wherein the manufacturing method prevents from the short circuit between the adjacent nodes at a precondition, which is the RAM device achieving the miniaturization requirements.

The manufacturing method for the nodes of the RAM device, includes: forming a shallow trench isolation (STI) layer on a substrate to divide the substrate into a plurality of active areas, wherein the adjacent portions of any two adjacent active areas and the portion of the STI layer arranged therebetween are defined as a unit region; sequentially forming a first insulating layer and a hard mask layer on the substrate, wherein the hard mask layer has a specific pattern; etching the first insulating layer of each unit region to form a first hole for exposing the STI layer of each unit region and partial of the active areas of each unit region; filling a conductive material in the first hole of each unit region to form a conductor; forming a protective layer on the top surface of the conductor of each unit region, wherein each protective layer has an opening aligning the STI layer of each unit region; etching the conductor of each unit region from the opening until the STI layer to form a second hole for exposing the STI layer of each unit region, wherein the aperture of the second hole is smaller than the aperture of the first hole, each conductor is divided into two nodes by the second hole arranged therebetween, and each node is used for electrically connecting to a capacitor; and forming a second insulating layer in the second hole of each unit region for electrically isolating the nodes of each unit region.

The random access memory (RAM) device is formed by the above manufacturing method.

Base on the above, at the precondition, which is the RAM device achieving the miniaturization requirements, the manufacturing method uses the laterally etching phenomenon by arranging the steps to form the protrusion of the second insulating layer for preventing from the short circuit between the adjacent nodes.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is a perspective view of a conventional RAM device;

FIG. 1A is an enlarge view of FIG. 1;

FIG. 2 is a perspective view of the step 110 of the manufacturing method of the instant disclosure;

FIG. 2A is a sectional view of FIG. 2;

FIG. 3 is a perspective view of the steps 120 and 130 of the manufacturing method of the instant disclosure;

FIG. 3A is a perspective view of the forming of the photoresist layer of the instant disclosure;

FIG. 4 is a perspective view of the step 140 of the manufacturing method of the instant disclosure;

FIG. 5 is a perspective view of the step 150 of the manufacturing method of the instant disclosure;

FIG. 6 is a perspective view of the step 160 of the manufacturing method of the instant disclosure;

FIG. 7 is a perspective view of the step 170 of the manufacturing method of the instant disclosure;

FIG. 8 is a perspective view of the step 180 of the manufacturing method of the instant disclosure;

FIG. 8A is an enlarge view of FIG. 8; and

FIG. 9 is a circuit view of the RAM device of the instant disclosure.

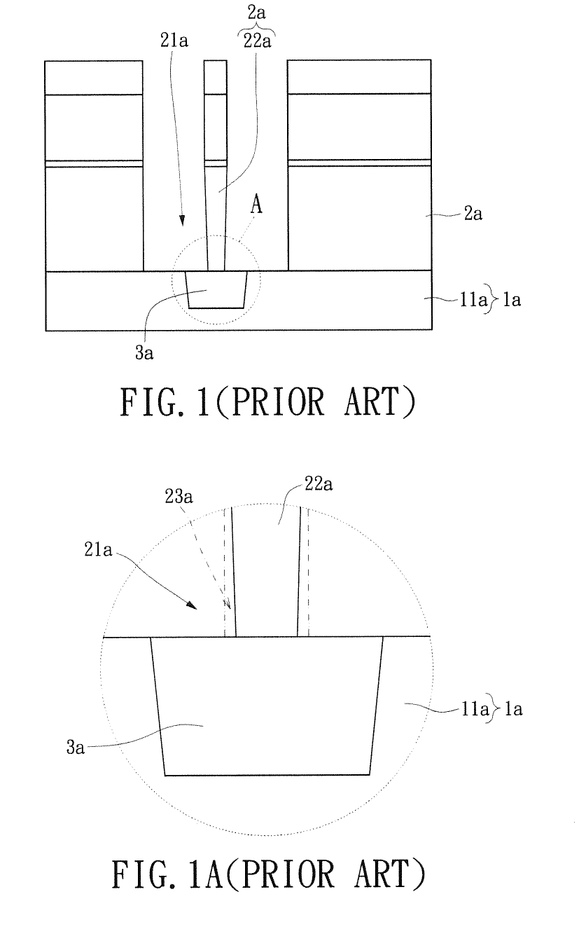

### DETAILED DESCRIPTION OF THE PREFERRED EMBODIMENTS

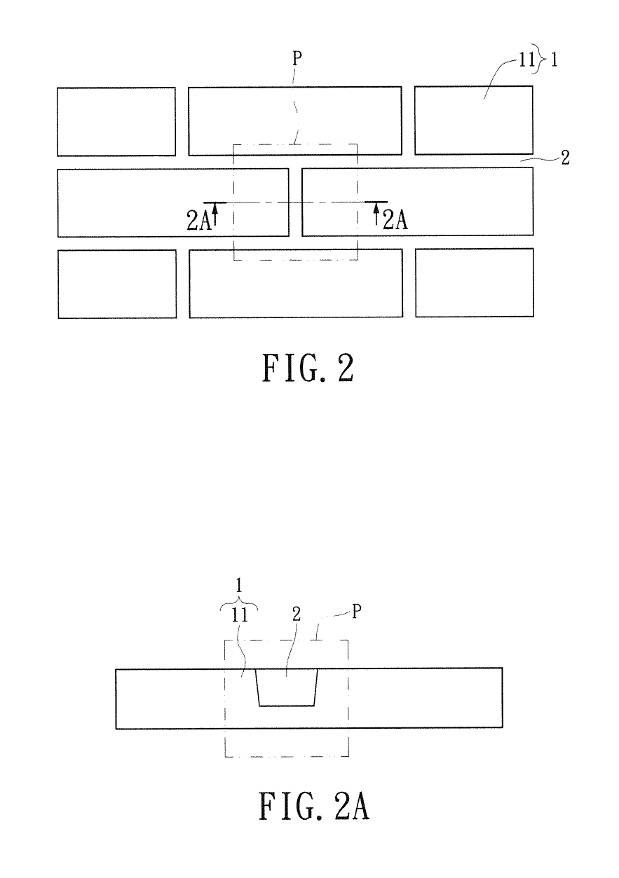

Please refer to FIGS. 2 to 9, which show an embodiment of the instant disclosure. The embodiment provides a manufacturing method for a plurality of nodes of a random access memory (RAM) device. The RAM device 100 in this embodiment takes Dynamic RAM (DRAM) device for example.

However, the RAM device 100 in use can be a static RAM (SRAM), an extended data output DRAM (EDO DRAM), a synchronous DRAM (SDRAM), a double data rate synchronous DRAM (DDR SDRAM), a synchronous link DRAM (SLDRAM), a video RAM (VRAM), a rambus DRAM (RDRAM), a flash memory, or the other memory type.

Please refer to FIGS. 2 and 2A, which are the perspective views of the step 110 and show one segment of a substrate 1. The segment of the substrate 1 is consisted of a plurality of unit regions P, and this embodiment takes one unit region P for example. FIG. 2 is the top view of the segment of the substrate 1, and FIG. 2A is the sectional view of FIG. 2.

Firstly, forming a shallow trench isolation (STI) layer 2 on the substrate 1 to divide the substrate 1 into a plurality of active areas 11. The adjacent portions of any two adjacent active areas 11 and the portion of the STI layer 2 arranged therebetween are defined as one unit region P.

The substrate 1 is made of epitaxial silicon, silicon, gallium arsenide, gallium nitride, strained silicon, silicon-germanium, silicon carbide, diamond, or the other material.

Specifically, the STI layer 2 is formed by the STI process. That is to say, etching the substrate 1 to form a trench (not shown), and then depositing an insulating material in the trench to form the STI layer, wherein the insulating material can be oxide or the other material having insulating property. Moreover, planarizing the substrate 1 and the STI layer 2 by implementing the chemical mechanical polishing (CMP) process.

The STI process and the CMP process are conventional means, so that this embodiment does not state the detail steps thereof.

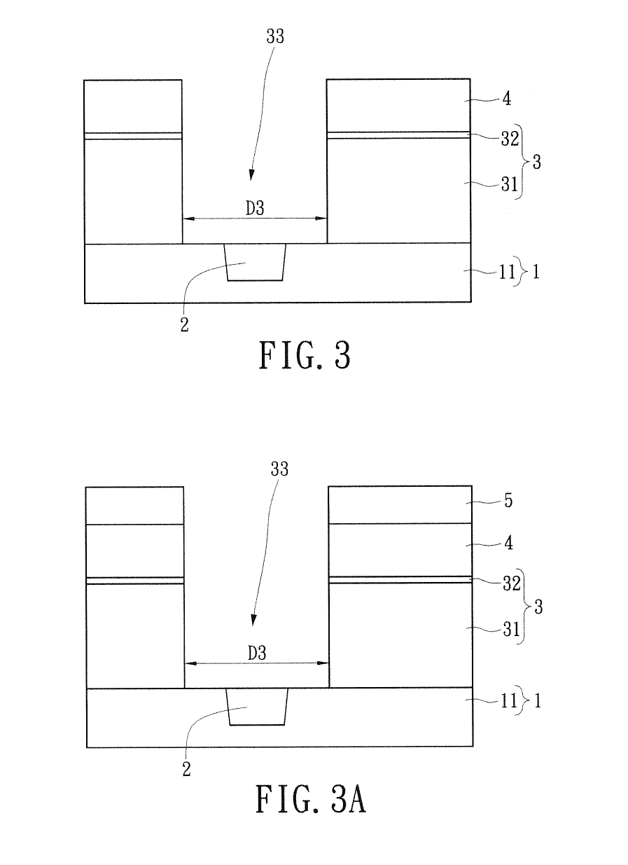

Please refer to FIG. 3, which is the perspective view of the step 120. Sequentially forming a first insulating layer 3 and a hard mask layer 4 on the substrate 1, wherein the hard mask layer 4 has a specific pattern.

The first insulating layer 3 has an oxide layer 31 and a silicon oxynitride layer 32. The oxide layer 31 is formed on the substrate 1 by implementing the deposit process, and the silicon oxynitride layer 32 is formed on the oxide layer 31 by implementing the deposit process. Moreover, the first insulating layer 3 can be the other material having insulating property, not be limited to this embodiment. The deposit process can be the physical vapor deposition (PVD) or the chemical vapor deposition (CVD), but not limited thereto.

Specifically, the forming of the hard mask layer 4 comprises: forming a photoresist layer 5 (as FIG. 3A shown) on the hard mask layer 4, and then forming the specific pattern of the hard mask layer 4 by the photoresist layer 5.

Please refer to FIG. 3, which is the perspective view of the step 130. Etching the first insulating layer 3 of each unit region P to form a first hole 33 for exposing the STI layer 2 of each unit region P and partial of the active areas 11 of each unit region P.

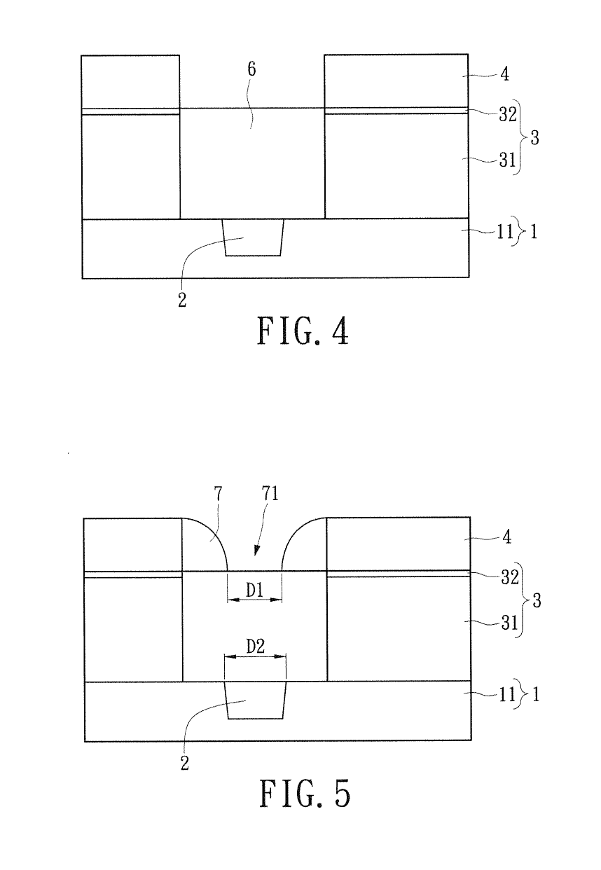

Please refer to FIG. 4, which is the perspective view of the step 140. Filling a conductive material in the first hole 33 of each unit region P to form a conductor 6. The conductive material includes at least one of polysilicon, titanium, titanium oxides, Platinum, chromium, tantalum, tantalum nitride, and wolfram.

Moreover, the forming of the conductor 6 of each unit region P comprises: implementing chemical mechanical polishing (CMP) and etching back for ensuring the conductor 6 of each unit region P be arranged in the first hole 33 and under the hard mask layer 4. Specifically, the top surface of each conductor 6 is coplanarly arranged to the top surface of the first insulating layer 3.

Please refer to FIG. 5, which is the perspective view of the step 150. Forming a protective layer 7 on the top surface of the conductor 6 of each unit region P. Each protective layer 7 has an opening 71 aligning the STI layer 2 of each unit region P.

Specifically, the aperture D1 of the opening 71 is approximately equal to the width D2 of the aligned portion of the STI layer 2, but not limited thereto. That is to say, the aperture D1 of the opening 71 can be smaller or larger than the width D2 of the aligned portion of the STI layer 2.

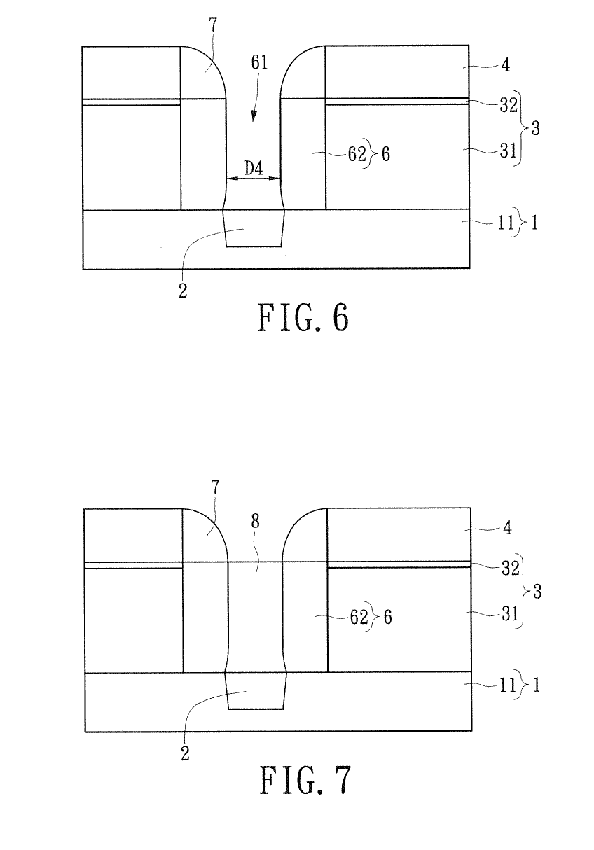

Please refer to FIG. 6, which is the perspective view of the step 160. Etching the conductor 6 of each unit region P from the opening 71 (as FIG. 5 shown) until the STI layer 2 to form a second hole 61 for exposing the STI layer 2 of each unit region P.

Moreover, the aperture D4 of the second hole 61 is smaller than the aperture D3 of the first hole 33. Each conductor 6 is divided into two nodes 61 by the second hole 61 arranged therebetween, and each node 62 is used for electrically connecting to a capacitor 10.

Specifically, when etching the conductor 6 of each unit region P to form the second hole 61, the lateral etch rate of each conductor 6 is gradually increased to gradually enlarge the aperture D4 of each second hole 61.

Please refer to FIG. 7, which is the perspective view of the step 170. Forming a second insulating layer 8 in the second hole 61 (as FIG. 6 shown) of each unit region P for electrically isolating the nodes 62 of each unit region P. Specifically, the section of the second insulating layer 8 of each unit region P is gradually increased along one direction defined from the top of the second insulating layer 8 to the substrate 1.

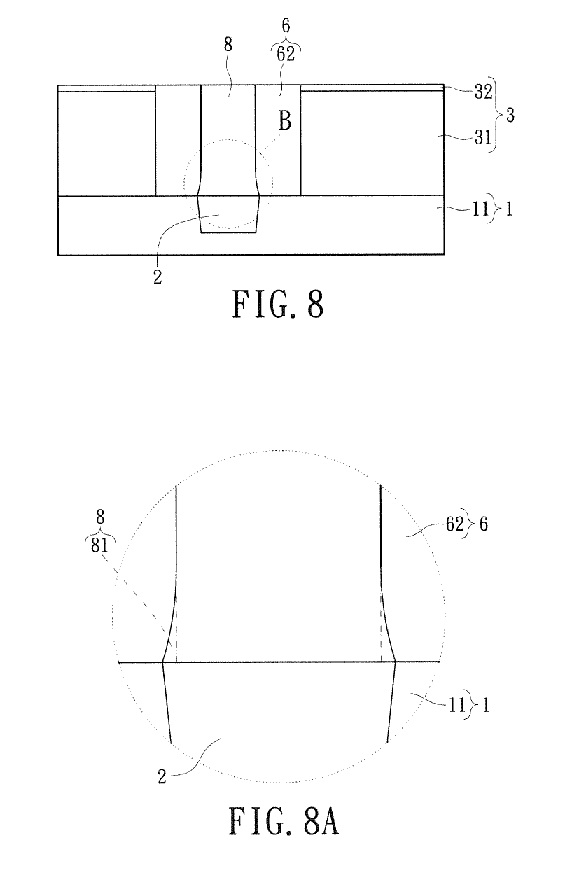

Please refer to FIG. 8, which is the perspective view of the step 180. After forming the second insulating layer 8, removing the hard mask layer 4 and the protective layer 7 of each unit region P, and making the top surface of the first insulating layer 3, the top surface of the nodes 62, and the top surface of the second insulating layer 8 of each unit region P to be arranged coplanar.

Specifically, if viewing the structure, which made by the above steps 110˜180, in the micro, the second insulating layer 8 of each unit region P has a protrusion 81 arranged on the periphery thereof by laterally etching each conductor 6. Each protrusion 81 is configured to insulate the adjacent nodes 62 of each unit region P, and each protrusion 81 is configured to prevent from the short circuit between the adjacent nodes 62 of each unit region P.

Moreover, the manufacturing method for the nodes in this embodiment takes the steps 110˜180 for example, but in use, the sequence of the steps can be changed or the other new step can be added.

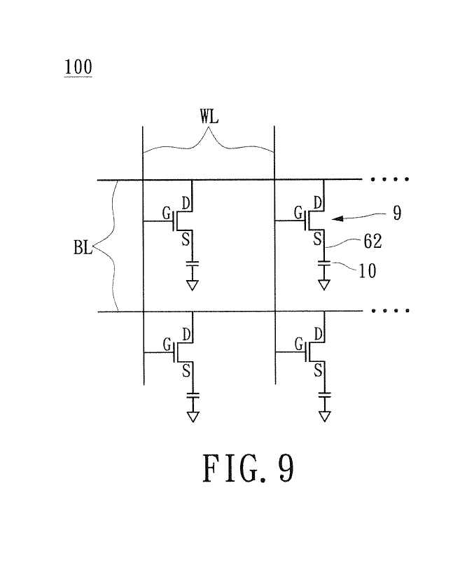

For example, before forming the nodes 62, forming a plurality of transistors 9 (as FIG. 9 shown) on the active areas 11 of the substrate 1. Specifically, the RAM device 100 further has the transistors 9 respectively formed on the active areas 11, a plurality of word lines WL, and a plurality of bit lines BL. The source electrode S of each transistor 9 is electrically connecting to each node 62 and the capacitor 10, which is connected to the node 62.

Moreover, the gate electrode G of each transistor 9 is electrically connecting to the adjacent word line WL; and the drain electrode D of each transistor 9 is electrically connecting to the adjacent bit line BL. That is to say, the unit regions P arranged on one word line WL are connected to the said word line WL; and the unit regions P arranged on one bit line BL are connected to the said bit line BL.

Thus, choosing the word line WL and the bit line BL to turn on the transistor 9 connected therebetween, so that the electric charge stored in the capacitor 10 can be detected for reading the data stored in the RAM device 100. Or, choosing the word line WL and the bit line BL to turn on the transistor 9 connected therebetween, so that an electric charge can be stored in the capacitor 10 for writing the data into the RAM device 100, and then turning off the transistor 9 to store the data in the RAM device 100.

The RAM device 100 in this embodiment is used for connecting to any electric circuit, for example, the electronic device (e.g., computer), which depends on the RAM device 100, has the electric circuit.

The computer includes a processor, a programmable logic controller, or the other substrate configuration, wherein the processor is a controlling circuit, a processing circuit, an universal single-chip, a multi-chip microprocessor, a digital signal microprocessor, an embedded microprocessor, or the other suitable type.

Moreover, each unit region P in this embodiment takes two nodes 62 formed at the same time for example, but in use, the unit region P can be expanded to form at least three nodes 62 at the same time.

Base on the above, at the precondition, which is the RAM device achieving the miniaturization requirements, the manufacturing method uses the laterally etching phenomenon by arranging the steps to form the protrusion of the second insulating layer for preventing from the short circuit between the adjacent nodes.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A manufacturing method for a plurality of nodes of a random access memory (RAM) device, comprising:
forming a shallow trench isolation (STI) layer on a substrate to divide the substrate into a plurality of active areas, wherein the adjacent portions of any two adjacent active areas and the portion of the STI layer arranged therebetween are defined as a unit region;
sequentially forming a first insulating layer and a hard mask layer on the substrate, wherein the hard mask layer has a specific pattern;
etching the first insulating layer of each unit region to form a first hole for exposing the STI layer of each unit region and partial of the active areas of each unit region;
filling a conductive material in the first hole of each unit region to form a conductor;
forming a protective layer on the top surface of the conductor of each unit region, wherein each protective layer has an opening aligning the STI layer of each unit region;
etching the conductor of each unit region from the opening until the STI layer to form a second hole for exposing the STI layer of each unit region, wherein the aperture of the second hole is smaller than the aperture of the first hole, each conductor is divided into two nodes by the second hole arranged therebetween, and each node is used for electrically connecting to a capacitor; and
forming a second insulating layer in the second hole of each unit region for electrically isolating the nodes of each unit region.

2. The manufacturing method as claimed in claim 1, wherein the forming of the conductor of each unit region comprises: implementing chemical mechanical polishing (CMP) and etching back for ensuring the conductor of each unit region be arranged in the first hole and under the hard mask layer.

3. The manufacturing method as claimed in claim 1, wherein after forming the second insulating layer, removing the hard mask layer and the protective layer.

4. The manufacturing method as claimed in claim 1, wherein the conductive material includes at least one of polysilicon, titanium, titanium oxides, Platinum, chromium, tantalum, tantalum nitride, and wolfram.

5. The manufacturing method as claimed in claim 1, wherein the forming of the hard mask layer comprises: forming a photoresist layer on the hard mask layer; and forming the specific pattern of the hard mask layer by the photoresist layer.

6. The manufacturing method as claimed in claim 1, wherein the first insulating layer has an oxide layer and a silicon oxynitride layer, and wherein the oxide layer is formed on the substrate, and the silicon oxynitride layer is formed on the oxide layer.

7. The manufacturing method as claimed in claim 1, wherein when etching the conductor of each unit region to form the second hole, the lateral etch rate of each conductor is gradually increased to gradually enlarge the aperture of each second hole.

8. A random access memory (RAM) device formed by the manufacturing method as claimed in claim 1.

9. The RAM device as claimed in claim 8, wherein the section of the second insulating layer of each unit region is gradually increased along one direction defined from the top of the second insulating layer to the substrate.

10. The RAM device as claimed in claim 8, further comprising a plurality of transistors respectively formed on the active areas, a plurality of word lines, and a plurality of bit lines, wherein the source electrode of each transistor is electrically connecting to each node, the gate electrode of each transistor is electrically connecting to the adjacent word line, and wherein the drain electrode of each transistor is electrically connecting to the adjacent bit line.
